(19) United States
(12) Patent Application Publication
(10) Pub. No.: US 2026/0106473 A1
(43) Pub. Date: Apr. 16, 2026

(54) CHARGING CASE AND EARPHONE KIT

(71) Applicant: Luxshare Precision Industry Company Limited, SHENZHEN (CN)

(72) Inventors: Shui Song Liu, SHENZHEN (CN); Heng Zhang, SHENZHEN (CN)

(73) Assignee: Luxshare Precision Industry Company Limited, SHENZHEN (CN)

(21) Appl. No.: 19/314,721

(22) Filed: Aug. 29, 2025

(30) Foreign Application Priority Data
Oct. 15, 2024 (CN) 202411445522.2

(51) Int. Cl. H02J 7/00; H04R 1/10; H05K 5/02; H05K 5/03

(52) U.S. Cl. CPC H02J 7/731; H04R 1/1025; H05K 5/0217; H05K 5/03

(57) ABSTRACT

A charging case includes an upper cover, a guiding member, a lower shell, a rotating shaft and a rotating member. The upper cover includes a cover body and an upper lining, the guiding member is fixed on the upper lining, the rotating shaft is fixed on the lower shell, the rotating member is rotationally arranged on the rotating shaft and connect the guiding member by sliding through the guiding groove, the rotating member is inclined towards a center of the lower shell when it is at a first position of the upper cover and is inclined towards the outside of the lower shell when it is at a second position of the upper cover. Therefore, the charging case lifts the upper cover through the rotation of the rotating member, so that the upper cover may avoid earphones when switching, so as to achieve the purpose of smooth switching.

### CLAIM OF PRIORITY AND CROSS-REFERENCE TO RELATED APPLICATION(S)

This application claims the benefit of Chinese Patent Application No. 202411445522.2, filed on Oct. 15, 2024, which is incorporated herein by reference in its entirety.

### BACKGROUND OF THE DISCLOSURE

### 1. Field of the Disclosure The present disclosure relates to the field of wireless earphones, and particularly to a charging case and an earphone kit.

### 2. Description of the Related Art

At present, most of the earphone charging cases on the market are opened by flipping or sliding, and the flipping mode usually requires two hands to access the product, which is inconvenient to operate. The sliding mode has limited the structure of the charging case due to the interference between the cover body and the earphones, which affects the processing and assembly efficiency of parts and the stability of the product.

### BRIEF DESCRIPTION OF THE DISCLOSURE

In view of this, the purpose of the present disclosure is to provide a charging case and an earphone kit, which may avoid the earphones when the upper cover is opened and closed by cooperating with the rotating member through the guiding groove set obliquely on the guiding member.

First, the embodiment of the disclosure provides a charging case, and the charging case comprises: an upper cover, comprising a cover body and an upper lining disposed within the cover body; a guiding member, fixedly disposed on the upper lining; a lower shell, forming an accommodating space with the upper cover to accommodate earphones; a rotating shaft, fixedly disposed on the lower shell; and a rotating member, wherein a lower end of the rotating member is rotatably disposed on the rotating shaft, an upper end of the rotating member is slidably connected to the guiding member, the rotating member tilts toward a center of the lower shell when the upper cover is in a first position, the rotating member tilts toward an outer side of the lower shell when the upper cover is in a second position, and a direction from the first position of the upper cover to the second position of the upper cover is an opening direction of the charging case.

In some embodiments, the guiding member is provided with a guiding groove extending from the first position of the upper cover to the second position of the upper cover and inclined downward, and the upper end of the rotating member is disposed within the guiding groove and slidably connected to the guiding member through the guiding groove.

In some embodiments, the charging case also includes: a torsion spring, sleeved on the rotating shaft, with two ends respectively connected to the rotating member and the lower shell.

In some embodiments, the lower shell is provided with a mounting groove, and the rotating shaft is disposed within the mounting groove; a lower end of the rotating member is provided with a fixing groove; an end of the torsion spring abuts against a side wall of the mounting groove, and another end of the torsion spring is fixedly disposed within the fixing groove.

In some embodiments, the mounting groove is provided with a step structure, and the step structure matches the lower end of the rotating member.

In some embodiments, the upper end of the rotating member is provided with a plurality of rolling beads, and the rolling beads are matched with the guiding groove to roll within the guiding groove.

In some embodiments, the rotating member comprises: a rotating portion, rotatably disposed on the rotating shaft; a sliding portion, located at an upper end of the rotating portion; and a mounting portion, disposed on the sliding portion, wherein the mounting portion is provided with the rolling beads.

In some embodiments, the mounting portion is provided with mounting holes, and the rolling beads are disposed within the mounting holes; the sliding portion is provided with avoiding grooves, and the avoiding grooves match the rolling beads.

In some embodiments, the charging case also comprises: a first magnet, disposed on the lower shell and located near the rotating member; a second magnet, disposed at the first position of the upper cover, configured to attract the first magnet when the rotating member is at the first position of the upper cover; and a third magnet, disposed at the second position of the upper cover, configured to attract the first magnet when the rotating member is at the second position of the upper cover.

In the second aspect, the embodiment of the disclosure also provides an earphone kit, and the earphone kit includes: the charging case as described in the first aspect; and earphones, accommodated within the charging case.

### BRIEF DESCRIPTION OF THE DRAWINGS

The above and other objectives, features, and advantages of the present disclosure will become clearer through the following description of embodiments of the present disclosure with reference to the accompanying drawings:

FIG. 1 is a structural diagram of a closed state of a charging case provided by an embodiment of the present disclosure;

FIG. 2 is a structural diagram of an open state of the charging case provided by an embodiment of the present disclosure;

FIG. 3 is an exploded diagram of the charging case provided by an embodiment of the present disclosure;

FIG. 4 is a sectional diagram of the closed state of the charging case provided by an embodiment of the present disclosure;

FIG. 5 is a sectional diagram of the open state of the charging case provided by an embodiment of the present disclosure;

FIG. 6 is a structural diagram of a guiding member provided by an embodiment of the present disclosure;

FIG. 7 is a structural diagram of an upper lining provided by an embodiment of the present disclosure;

FIG. 8 is a structural diagram of a lower lining provided by an embodiment of the present disclosure;

FIG. 9 is a structural diagram of a rotating member provided by an embodiment of the present disclosure;

FIG. 10 is a structural diagram of a partial structure of the rotating member provided by an embodiment of the present disclosure.

### DETAILED DESCRIPTION OF EMBODIMENTS OF THE DISCLOSURE

The following describes the present application based on embodiments, but the present application is not limited to these embodiments. In the following detailed description of the present application, specific details are described in detail. For those skilled in the art, the present application may be fully understood without the description of these detailed parts. To avoid confusion of the essence of the present application, the well-known methods, processes, procedures, components, and circuits have not been described in detail.

In addition, ordinary technical personnel in this field should understand that the accompanying drawings provided here are for illustrative purposes and may not necessarily be drawn to scale.

Unless otherwise specified and limited, the terms “installation”, “connection”, “coupling”, “fixation”, etc. should be broadly understood, for example, they may be fixed connections, detachable connections, or integrated. It may be a mechanical connection or an electrical connection. It may be directly connected or indirectly connected through an intermediate medium, and may be a connection within two components or an interaction relationship between two components, unless otherwise specified. For ordinary technical personnel in this field, the specific meanings of the above terms in this application may be understood according to the specific situation.

For ease of explanation, spatial terms such as “inside”, “outside”, “lower”, “below”, “under”, “upper”, “above”, etc. are used here to describe the relationship between one element or feature illustrated in the figure and another element or feature. It will be understood that space related terms may imply different orientations of the device during use or operation, apart from those depicted in the diagram. For example, if the device in the figure is flipped, the component described as being “below” or “under” other components or features will then be positioned “above” that other component or feature. Therefore, the example term “below” may encompass both the directions above and below. The device may be oriented in other ways (rotated 90 degrees or in other orientations), and the spatial descriptors used here should be explained accordingly.

Unless explicitly required by the context, words such as “including” and “containing” in the entire application document should be interpreted as containing rather than exclusive or exhaustive. That is to say, it means “including but not limited to”.

In the description of this application, it should be understood that the terms “first”, “second”, etc. are only used for descriptive purposes and cannot be understood as indicating or implying relative importance. In addition, in the description of this application, unless otherwise specified, the meaning of “multiple”refers to two or more.

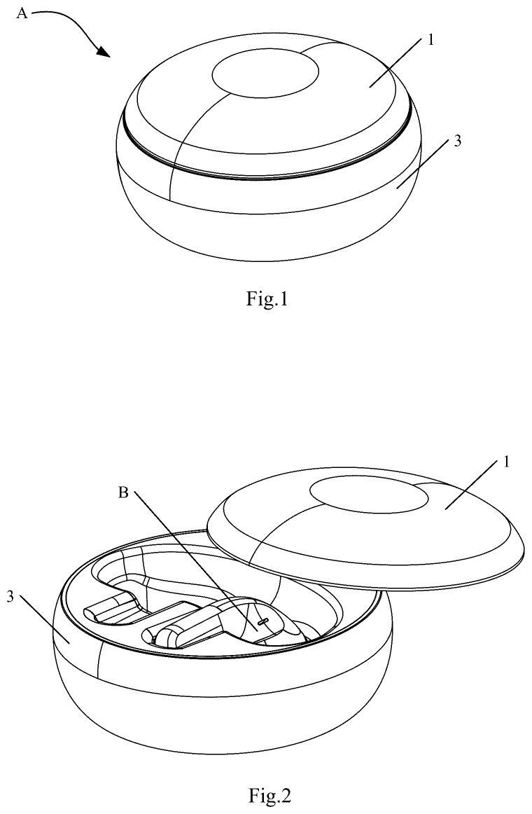

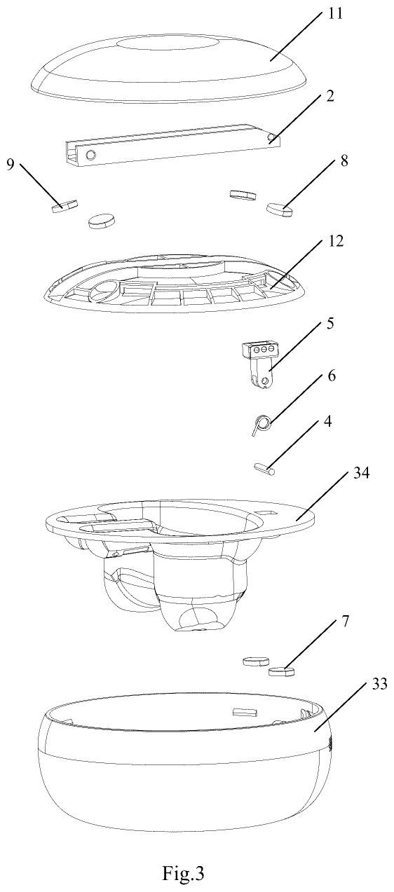

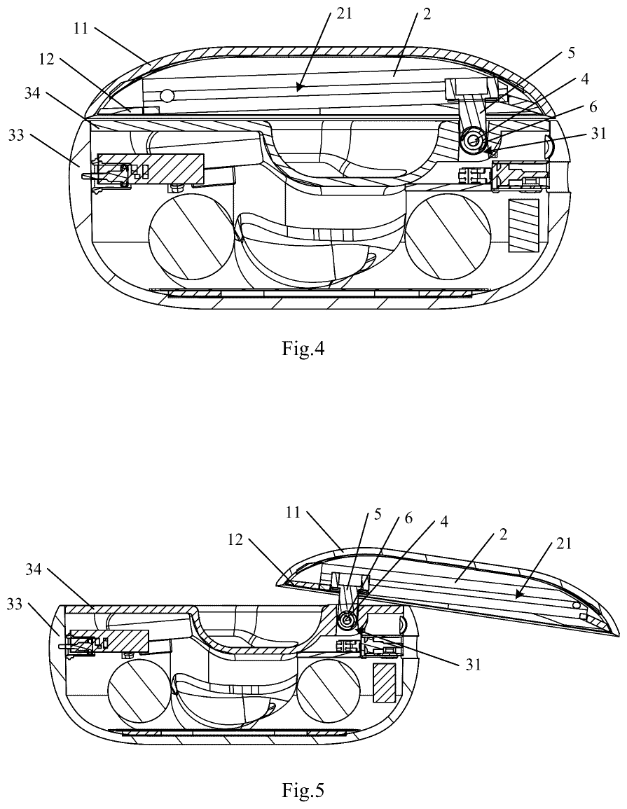

FIG. 1 is a structural diagram of a closed state of a charging case provided by an embodiment of the present disclosure, and FIG. 2 is a structural diagram of an open state of the charging case provided by an embodiment of the present disclosure. As shown in FIG. 1 and FIG. 2, the charging case A includes an upper cover 1 and a lower shell 3, and an accommodating space is formed between the upper cover 1 and the lower shell 3 to accommodate earphones B. Further, FIG. 3 is an exploded diagram of the charging case provided by an embodiment of the present disclosure, FIG. 4 is a sectional diagram of the closed state of the charging case provided by an embodiment of the present disclosure, and FIG. 5 is a sectional diagram of the open state of the charging case provided by an embodiment of the present disclosure, as shown in FIG. 3, FIG. 4 and FIG. 5, the charging case A also includes a guiding member 2, a rotating shaft 4 and a rotating member 5. Specifically, the guiding member 2 is fixedly arranged on the upper cover 1, the rotating shaft 4 is fixedly arranged on the lower shell 3, a lower end of the rotating member 5 is rotationally arranged on the rotating shaft 4, and an upper end of the rotating member 5 is sliding connected with the guiding member 2. It should be noted that, as shown in FIG. 4 and FIG. 5, a first position and a second position are two opposite positions on the upper cover 1. When the charging case A is closed, the rotating member 5 is located at the first position of the upper cover 1, and when the charging case A is open, the rotating member 5 is located at the second position of the upper cover 1. Further, as shown in FIG. 4, the rotating member 5 inclines towards a center of the lower shell 3 when the rotating member 5 is at the first position of the upper cover 1. Correspondingly, as shown in FIG. 5, when the rotating member 5 is at the second position of the upper cover 1, the rotating member 5 inclines towards the outside of the lower shell 3. When the charging case A changes from the closed state to the open state or from the open state to the closed state, during the sliding of the upper cover 1, the rotating member 5 rotates and straightens to raise the upper cover 1, so as to avoid interference between the upper cover 1 and the earphones B.

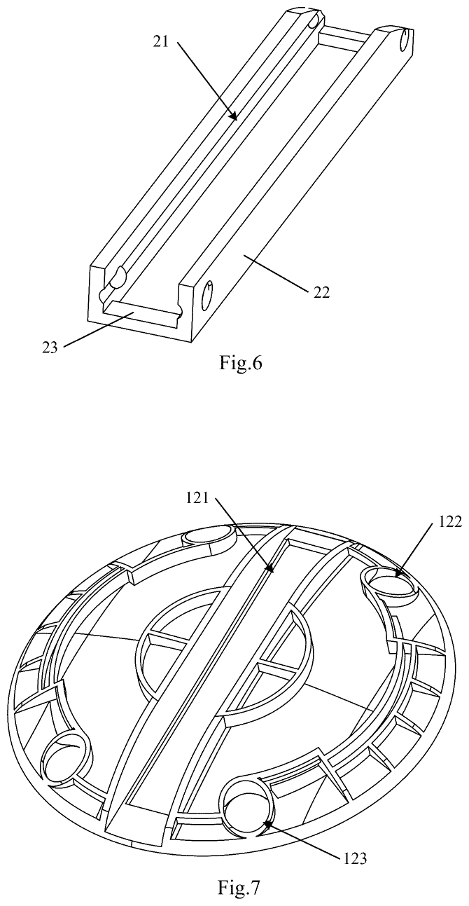

Further, FIG. 6 is a structural diagram of a guiding member provided by an embodiment of the present disclosure. As shown in FIG. 4, FIG. 5 and FIG. 6, the guiding member 2 is provided with a guiding groove 21. As shown in FIG. 6, the guiding member 2 includes two side plates 22 and two connecting rods 23, and the two connecting rods 23 are connected at two ends of each side plate 22. Further, there are two guiding grooves 21, and each side plate 22 is provided with a guiding groove 21. It is easy to understand that the upper end of the rotating member 5 is connected with the guiding member 2 through two guiding grooves 21. Thus, when the user pushes the upper cover 1, the rotating member 5 may rotate while sliding relative to the upper cover 1.

As shown in FIG. 4, the guiding grooves 21 extends from the first position of the upper cover 1 to the second position of the upper cover 1 and inclines downwards. Thus, the charging case A may avoid the earphones B placed in the charging case A by setting the rotatable rotating member 5 to cooperate with the guiding grooves 21 set obliquely, so that the upper cover 1 may be lifted upward during the opening or closing process. For example, when the charging case A changes from the closed state to the open state or from the open state to the closed state, the upper cover 1 first slides diagonally upward, while the rotating member 5 rotates and straightens; then the upper cover 1 slides horizontally until the rotating member 5 deflects into place; finally, the upper cover 1 slides downward obliquely, thus completing the sliding action of avoiding the earphones B.

As shown in FIG. 3, FIG. 4 and FIG. 5, in one embodiment, the upper cover 1 comprises a cover body 11 and an upper lining 12 arranged in the cover body 11, and the lower shell 3 comprises a shell body 33 and a lower lining 34 arranged in the shell body 33. Further, the guiding member 2 is arranged on the upper lining 12, the rotating shaft 4 is arranged on the lower lining 34, and the rotating member 5 is arranged on the lower lining 34 through the rotating shaft 4. It is easy to understand that the charging case A may easily adjust the structure for earphones B through the upper lining 12 and the lower lining 34, thus helping to improve the applicability and reduce costs.

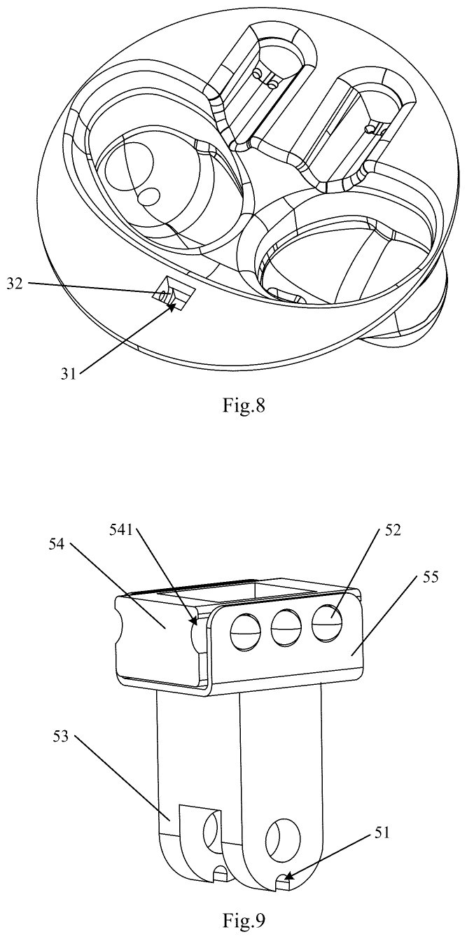

FIG. 7 is a structural diagram of an upper lining provided by an embodiment of the present disclosure. As shown in FIG. 7, in one embodiment, a center of the upper lining 12 is provided with a long vent hole 121. Specifically, the vent hole 121 is arranged as a rectangle and matched with the guiding member 2, and the guiding member 2 is arranged at the position of the vent hole 121. Thus, the upper end of the rotating member 5 may pass through the vent hole 121 to fit with the guiding grooves 21 on the guiding member 2.

As shown in FIG. 3, FIG. 4 and FIG. 5, in one embodiment, the charging case A also includes a torsion spring 6. It should be noted that the torsion spring 6 is set on the rotating shaft 4, and two ends of the torsion spring 6 are respectively connected with the rotating member 5 and the lower shell 3. It is easy to understand that when the upper cover 1 is opened or closed by sliding, the rotating member 5 rotates, so that the torsion spring 6 twists. Therefore, when the upper cover 1 is opened or closed, the torsion spring 6 may use the elastic force to boost the power of the rotating member 5, thus improving the user's experience.

FIG. 8 is a structural diagram of a lower lining provided by an embodiment of the present disclosure. As shown in FIG. 8, in one embodiment, the lower lining 34 is provided with a mounting groove 31, that is, the lower shell 3 is provided with a mounting groove 31. As shown in FIG. 4 and FIG. 5, the rotating shaft 4 is arranged in the mounting groove 31. Furthermore, FIG. 9 is a structural diagram of a rotating member provided by an embodiment of the present disclosure. As shown in FIG. 9, the lower end of the rotating member 5 is provided with a fixing groove 51. It should be noted that one end of the torsion spring 6 butts against the inner wall of the mounting groove 31, and the other end of the torsion spring 6 is fixedly arranged in the fixing groove 51. Thus, when the upper cover 1 slides, the rotating member 5 rotates around the rotating shaft 4, and the lower end of the rotating member 5 drives one end of the torsion spring 6 to move, so that the torsion spring 6 may be twisted synchronously, and thus the torsion spring 6 may use the elastic force to assist the rotating member 5, so as to improve the user's experience.

As shown in FIG. 8, in one embodiment, the mounting groove 31 is provided with a step structure 32. Specifically, the step structure 32 matches the lower end of the rotating member 5. It should be noted that a curved surface is formed on the step structure 32 to adapt to the rotational motion of the rotating member 5. Therefore, the step structure 32 arranged in the mounting groove 31 may support and limit the rotating member 5.

As shown in FIG. 9, in one embodiment, the upper end of the rotating member 5 is provided with a plurality of rolling beads 52. It is easy to understand that the plurality of rolling beads 52 are arranged on both sides of the rotating member 5 to fit the two guiding grooves 21 on the guiding member 2. For example, the two sides of the rotating member 5 are respectively provided with three rolling beads 52 spaced along a straight line. Specifically, the rolling beads 52 are matched with the guiding grooves 21, so that the rolling beads 52 may be rolled and set in the guiding grooves 21. It is easy to understand that the smoothness of relative sliding between the rotating member 5 and the upper cover 1 may be improved by setting the rolling beads 52.

As shown in FIG. 9, in one embodiment, the rotating member 5 includes a rotating portion 53, a sliding portion 54 and a mounting portion 55. Specifically, the rotating portion 53 is rotationally arranged on the rotating shaft 4, the sliding portion 54 is located on an upper end of the rotating portion 53, and the mounting portion 55 is arranged on the sliding portion 54. Optionally, the sliding portion 54 adapts to the guiding member 2 and is arranged in a cuboid structure, and the mounting portion 55 is fixedly arranged on the outside of the sliding portion 54. Further, a plurality of rolling beads 52 are spaced on the mounting portion 55, so that they may roll along the guiding grooves 21 under the limiting action of the mounting portion 55. Optionally, the rotating portion 53 is provided with a fork structure so that the torsion spring 6 may be arranged within the gap formed by the rotating portion 53.

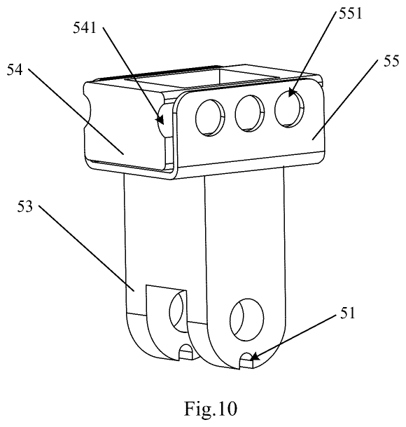

FIG. 10 is a structural diagram of a partial structure of the rotating member provided by an embodiment of the present disclosure, as shown in FIG. 10, in one embodiment, the mounting portion 55 is provided with a plurality of mounting holes 551, and the plurality of rolling beads 52 are arranged in the corresponding mounting holes 551. It is easy to understand that the shape and size of mounting holes 551 and rolling beads 52 match each other, so that the limiting effect of mounting holes 551 on rolling beads 52 may be ensured. Further, as shown in FIG. 9 and FIG. 10, the sliding portion 54 is provided with avoiding grooves 541, and the avoiding grooves 541 are matched with the rolling beads 52. For example, the bottom of each avoiding groove 541 is set as a curved surface, and the bottom of each guiding groove 21 is also set as a curved surface, so as to ensure that the rolling beads 52 may roll smoothly, thus ensuring that the upper cover 1 may slide smoothly.

As shown in FIG. 3, in one embodiment, the charging case A also includes a first magnet 7, a second magnet 8 and a third magnet 9. Specifically, the first magnet 7 is arranged on the lower shell 3 and is located near the rotating member 5. Optionally, the first magnet 7 is arranged in a cavity between the shell body 33 and the lower lining 34. Further, the second magnet 8 is arranged at the first position of the upper cover 1, and the third magnet 9 is arranged at the second position of the upper cover 1. Optionally, as shown in FIG. 7, an upper surface of the upper lining 12 is provided with a first accommodating groove 122 and a second accommodating groove 123. The first accommodating groove 122 is located at the first position of the upper cover 1 and is matched with the second magnet 8 to accommodate the second magnet 8. The second accommodating groove 123 is located at the second position of the upper cover 1 and is matched with the third magnet 9 to accommodate the third magnet 9. Further, when the rotating member 5 is at the first position of the upper cover 1, the second magnet 8 attracts the first magnet 7, thus ensuring the closing effect of the upper cover 1. Correspondingly, when the rotating member 5 is at the second position of the upper cover 1, the third magnet 9 attracts the first magnet 7, thus ensuring the opening effect of the upper cover 1. In this embodiment, the charging case A includes two first magnets 7 and the two first magnets 7 are spaced on both sides of the rotating member 5, the charging case A includes two second magnets 8 and the two second magnets 8 are spaced on both sides of the guiding member 2, and the charging case A includes two third magnets 9 and the two third magnets 9 are spaced on both sides of the guiding member 2, so that the stability of the attraction structure may be guaranteed, and thus the switching effect of the upper cover 1 may be guaranteed. Optionally, the upper surface of the upper lining 12 is provided with two first accommodating grooves 122 to accommodate two second magnets 8, and the upper surface of the upper lining 12 is provided with two second accommodating grooves 123 to accommodate two third magnets 9.

The embodiment of the disclosure also provides an earphone kit, which includes a charging case A and earphones B. It should be noted that the structure of the charging case A is as described above, and will not be repeated here. Further, the earphones B are accommodated in the charging case A. Therefore, when using the earphone kit, the user may open or close the upper cover 1 by rotating and sliding, so that the upper cover 1 may avoid the earphones B, so that the earphones B may be easily taken and placed.

The embodiment of the disclosure provides a charging case and an earphone kit, the earphone kit includes an upper cover, a guiding member, a lower shell, a rotating shaft and a rotating member. The upper cover includes a cover body and an upper lining arranged in the cover body. The guiding member is fixedly arranged on the upper lining. A guiding groove extends from a first position of the upper cover to a second position of the upper cover and inclines downwards. The rotating shaft is fixedly arranged on the lower shell. A lower end of the rotating member is rotationally arranged on the rotating shaft. An upper end of the rotating member is sliding connected with the guiding member through the guiding groove. When the rotating member is in the first position of the upper cover, it inclines towards a center of the lower shell. When the rotating member is in the second position of the upper cover, it inclines towards the outside of the lower shell. The first position of the upper cover towards the second position of the upper cover is the opening direction of the charging case. Therefore, the rotation of the rotating member of the charging case lifts the upper cover so that when the upper cover is opened and closed, the earphones may be avoided, so as to achieve the purpose of sliding the switch.

The above description is only a preferred embodiment of the present application and is not intended to limit the present application. For those skilled in the art, the present application may have various modifications and variations. Any modifications, equivalent substitutions, improvements, etc. made within the spirit and principles of this application should be included within the scope of protection of this application.

I/We claim:

1. A charging case, comprising:
an upper cover (1), comprising a cover body (11) and an upper lining (12) disposed within the cover body (11);
a guiding member (2), fixedly disposed on the upper lining (12);
a lower shell (3), forming an accommodating space with the upper cover (1) to accommodate earphones (B);
a rotating shaft (4), fixedly disposed on the lower shell (3); and
a rotating member (5), wherein a lower end of the rotating member (5) is rotatably disposed on the rotating shaft (4), an upper end of the rotating member (5) is slidably connected to the guiding member (2), the rotating member (5) tilts toward a center of the lower shell (3) when the upper cover (1) is in a first position, the rotating member (5) tilts toward an outer side of the lower shell (3) when the upper cover (1) is in a second position, and a direction from the first position of the upper cover (1) to the second position of the upper cover (1) is an opening direction of the charging case (A).

2. The charging case according to claim 1, wherein the guiding member (2) is provided with a guiding groove (21) extending from the first position of the upper cover (1) to the second position of the upper cover (1) and inclined downward, and the upper end of the rotating member (5) is disposed within the guiding groove (21) and slidably connected to the guiding member (2) through the guiding groove (21).

3. The charging case according to claim 2, wherein the guiding member (2) includes two side plates (22) and two connecting rods (23), the two connecting rods (23) are connected at two ends of each side plate (22), and each side plate (22) is provided with a guiding groove (21).

4. The charging case according to claim 1, wherein the lower shell (3) comprises a shell body (33) and a lower lining (34) arranged in the shell body (33), the rotating shaft (4) is arranged on the lower lining (34), and the rotating member (5) is arranged on the lower lining (34) through the rotating shaft (4).

5. The charging case according to claim 4, wherein a center of the upper lining (12) is provided with a long vent hole (121), the guiding member (2) is arranged at a position of the vent hole (121), the rotating member (5) passes through the vent hole (121) to fit with guiding grooves (21) on the guiding member (2).

6. The charging case according to claim 1, further comprising:
a torsion spring (6), sleeved on the rotating shaft (4), with two ends respectively connected to the rotating member (5) and the lower shell (3).

7. The charging case according to claim 6, wherein the lower shell (3) is provided with a mounting groove (31), and the rotating shaft (4) is disposed within the mounting groove (31);
a lower end of the rotating member (5) is provided with a fixing groove (51);
an end of the torsion spring (6) abuts against a side wall of the mounting groove (31), and another end of the torsion spring (6) is fixedly disposed within the fixing groove (51).

8. The charging case according to claim 7, wherein the mounting groove (31) is provided with a step structure (32), and the step structure (32) matches the lower end of the rotating member (5).

9. The charging case according to claim 2, wherein the upper end of the rotating member (5) is provided with a plurality of rolling beads (52), and the rolling beads (52) are matched with the guiding groove (21) to roll within the guiding groove (21).

10. The charging case according to claim 9, wherein the rolling beads (52) are arranged on both sides of the upper end of the rotating member (5).

11. The charging case according to claim 9, wherein the rotating member (5) comprises:
a rotating portion (53), rotatably disposed on the rotating shaft (4);
a sliding portion (54), located at an upper end of the rotating portion (53); and
a mounting portion (55), disposed on the sliding portion (54), wherein the mounting portion

(55) is provided with the rolling beads (52).

12. The charging case according to claim 11, wherein the mounting portion (55) is provided with mounting holes (551), and the rolling beads (52) are disposed within the mounting holes (551);
the sliding portion (54) is provided with avoiding grooves (541), and the avoiding grooves (541) match the rolling beads (52).

13. The charging case according to claim 12, wherein a bottom of each avoiding groove (541) is set as a curved surface, and a bottom of each guiding groove (21) is set as a curved surface.

14. The charging case according to claim 1, further comprising:
a first magnet (7), disposed on the lower shell (3) and located near the rotating member (5);
a second magnet (8), disposed at the first position of the upper cover (1), configured to attract the first magnet (7) when the rotating member (5) is at the first position of the upper cover (1); and
a third magnet (9), disposed at the second position of the upper cover (1), configured to attract the first magnet (7) when the rotating member (5) is at the second position of the upper cover (1).

15. An earphone kit, comprising:
the charging case (A) according to claim 1; and
earphones (B), accommodated within the charging case (A).

16. The earphone kit according to claim 15, wherein the guiding member (2) is provided with a guiding groove (21) extending from the first position of the upper cover (1) to the second position of the upper cover (1) and inclined downward, and the upper end of the rotating member (5) is disposed within the guiding groove (21) and slidably connected to the guiding member (2) through the guiding groove (21).

17. The earphone kit according to claim 15, further comprising:
a torsion spring (6), sleeved on the rotating shaft (4), with two ends respectively connected to the rotating member (5) and the lower shell (3).

18. The earphone kit according to claim 17, wherein the lower shell (3) is provided with a mounting groove (31), and the rotating shaft (4) is disposed within the mounting groove (31);
a lower end of the rotating member (5) is provided with a fixing groove (51);
an end of the torsion spring (6) abuts against a side wall of the mounting groove (31), and another end of the torsion spring (6) is fixedly disposed within the fixing groove (51).

19. The earphone kit according to claim 18, wherein the mounting groove (31) is provided with a step structure (32), and the step structure (32) matches the lower end of the rotating member (5).

20. The earphone kit according to claim 16, wherein the upper end of the rotating member (5) is provided with a plurality of rolling beads (52), and the rolling beads (52) are matched with the guiding groove (21) to roll within the guiding groove (21).
